(19) United States
(12) Patent Application Publication
(10) Pub. No.: US 2026/0342072 A1
(43) Pub. Date: Oct. 29, 2026

(54) CIRCUIT CUT-OFF TRIGGERING DEVICE

(71) Applicant: EVE ENERGY CO., LTD., Huizhou (CN)

(72) Inventor: Rubang ZHAO, Huizhou (CN)

(73) Assignee: EVE ENERGY CO., LTD., Huizhou (CN)

(21) Appl. No.: 19/651,495

(22) Filed: Apr. 17, 2026

Related U.S. Application Data
(63) Continuation of application No. PCT/CN2024/115914, filed on Aug. 30, 2024.

(30) Foreign Application Priority Data
Nov. 17, 2023 (CN) 202311540808.4
Nov. 17, 2023 (CN) 202323116842.7

(51) Int. Cl. H02H 1/00; G01R 19/165; H02H 7/18

(52) U.S. Cl. CPC H02H 1/0007; G01R 19/16528; H02H 7/18

(57) ABSTRACT

A circuit cut-off triggering device is provided. The device includes a determination circuit configured to integrate a voltage collected from a shunt in a target circuit to obtain an integral voltage. A triggering signal is generated to cut off the target circuit when the integral voltage reaches a first threshold. The device is configured such that the time required to reach the first threshold is inversely proportional to the magnitude of the voltage across the shunt. This ensures that the cut-off time decreases as current increases, preventing the exponential increase in heat generation and component damage associated with traditional fixed-time triggers.

### CROSS-REFERENCE TO RELATED APPLICATIONS

This application is a bypass continuation application of International Application No. PCT/CN2024/115914, filed on Aug. 30, 2024, which claims priority to and the benefit of Chinese Application Nos. 202323116842.7 and 202311540808.4, both filed on Nov. 17, 2023. The entire contents of the above-referenced applications are expressly incorporated herein by reference.

### TECHNICAL FIELD

The present application relates to the field of battery protection technology, and particularly to a circuit cut-off triggering device.

### BACKGROUND

In related technologies, current in a circuit is detected by a trigger of a Micro Controller Unit (MCU) and evaluated through a predetermined process, and the circuit is triggered to be cut off at both low voltage and high voltage after a constant time.

In a high-voltage circuit, current I is usually large. Defining a time for a trigger to cut off the high-voltage circuit as t, a Joule integral I²t sustained by electrical components in the high-voltage circuit before cutting off increases exponentially with an increase in the current I. Therefore, the electrical components generate a large amount of heat before the high-voltage circuit is cut off by the trigger, which easily causes damage to the electrical components and is very dangerous. As such, the cutoff methods relying on trigger detection provides poor protection of the circuit under high current conditions.

### SUMMARY

Embodiments of the present disclosure provide a circuit cut-off triggering device, including a determination circuit configured to integrate a voltage across a shunt to obtain a corresponding integral voltage, and generate a triggering signal in case that the integral voltage reaches a first threshold. The triggering signal is configured to cause a target circuit to be cut off. A time for the integral voltage to reach the first threshold is inversely proportional to a magnitude of a voltage across the shunt.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the disclosure.

FIG. 1 is a schematic diagram of a module of an exemplary triggering device for circuit cut-off and its application scenario provided in an embodiment of the present disclosure.

FIG. 2 is a schematic diagram of a module of an exemplary triggering device for circuit cut-off provided in an embodiment of the present disclosure.

FIG. 3 is a schematic diagram of a module of an exemplary determination circuit provided in an embodiment of the present disclosure.

FIG. 4 is a schematic diagram of a structure of an exemplary integrating circuit provided in an embodiment of the present disclosure.

FIG. 5 is a schematic diagram of a structure of an exemplary differential amplifying circuit provided in an embodiment of the present disclosure.

FIG. 6 is a schematic diagram of a structure of an exemplary absolute value multiplying circuit provided in an embodiment of the present disclosure.

FIG. 7 is a schematic diagram of a structure of an exemplary threshold judgment circuit provided in an embodiment of the present disclosure.

FIG. 8 is a schematic diagram of a structure of an exemplary determination triggering circuit provided in an embodiment of the present disclosure.

FIG. 9 is a schematic diagram of a structure of an exemplary triggering circuit provided in an embodiment of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented.

The safety of short-circuit protection depends on an I²t value in a circuit, in which I is a current in the circuit, and t is a time from sensing an excessive current in the circuit to the circuit being cut off by a protection component such as a trigger. The smaller the I²t value is, the less damage is sustained by an entire high-voltage circuit.

In related technologies, a current in a circuit is detected by a trigger of a Micro Controller Unit (MCU), evaluated through a predetermined process, and the circuit is triggered to be cut off at both low voltage and high voltage after a constant time t. As the time t for the trigger to cut off the circuit remains unchanged, a Joule integral I²t sustained by the circuit during a cut-off process increases exponentially with an increase in the current I, resulting in poor protection under high current conditions.

For example, a current in a circuit is detected and logically processed by the MCU, and once the current reaches a threshold, a trigger is controlled to cut off the circuit. The detection of the current in the circuit is logically processed by the MCU and an MCU logic operation time is constant, therefore the time for the trigger to cut off the circuit in this method is long and constant. In a high-voltage circuit, the current in the high-voltage circuit is large, and the Joule integral I²t sustained by the circuit during a cut-off process increases exponentially with an increase in the current I, which eventually leads to technical problems such as damage to electrical components. Due to physical properties of a traditional fuse, the I²t value of the traditional fuse varies with the current value, and the I²t is large when the current is small.

Embodiments of the present disclosure provide a circuit cut-off triggering device 100 to address the technical problems in conventional solutions.

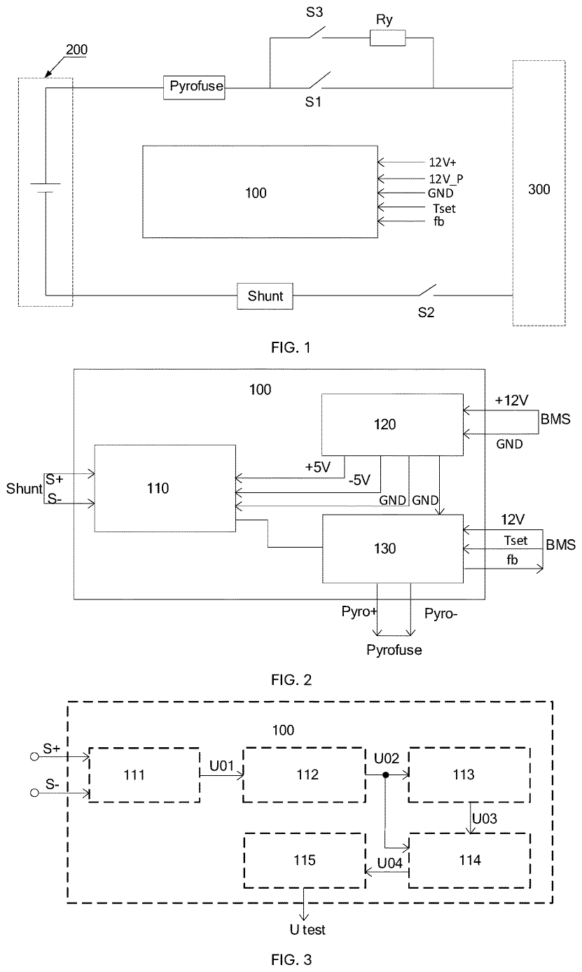

Referring to FIG. 1 to FIG. 9, the circuit cut-off triggering device 100 includes a determination circuit 110. The determination circuit 110 is electrically connected to a shunt of a target circuit. The determination circuit 110 evaluates a voltage across the target circuit by collecting voltage across the shunt. The shunt is a resistor R with a specific resistance value. The determination circuit 110 integrates the voltage across the shunt to obtain a corresponding integral voltage. Since the voltage across the shunt may change dynamically, the integration process also occurs in real-time.

The voltage across the shunt determines the magnitude of the integral voltage within the corresponding time, that is, within a certain period, the higher the voltage across the shunt is, the higher the corresponding integral voltage is. Therefore, the higher the voltage across the shunt is, the shorter the time it will take for the integral voltage to reach a first threshold, that is, the time for the integral voltage to reach the first threshold is inversely proportional to the magnitude of the voltage across the shunt.

Once the integral voltage reaches the first threshold, the circuit cut-off triggering device 100 generates a triggering signal, which drives a protection device Pyrofuse in the target circuit to perform a protection action, such as cutting off the target circuit.

The voltage across the shunt is U=IR, in which I is a current flowing through the shunt, and R is a resistance of the shunt. Thus, a Joule integral sustained by the target circuit is I²t, in which tis a time for the circuit cut-off triggering device 100 to sense the voltage across the shunt and trigger the protection device Pyrofuse to cut off the target circuit.

Referring to FIG. 2, based on a scheme of the circuit cut-off triggering device 100 in this embodiment, the higher the voltage across the shunt, the shorter the time for the integral voltage generated by determination circuit 110 to reach the first threshold. In case that a value of the first threshold is preset, the higher the voltage across the target circuit is, that is, the greater the current is (I=U/R), the shorter the time t is for the determination circuit 110 to generate a triggering signal to trigger the protection device Pyrofuse to cut off the circuit.

Based on the scheme of the circuit cut-off triggering device 100 in this embodiment, the Joule integral expected to be sustained by the target circuit during a cut-off process is set as the first threshold. Thus, the Joule integral sustained by the target circuit during the cut-off process is of constant value. A time for cutting off the target circuit under large current conditions is less than a time for cutting off the target circuit under small current conditions. The Joule integral sustained by the target circuit during the cut-off process under large current conditions is the same as the Joule integral sustained by the target circuit during the cut-off process under small current conditions, so that the Joule integral I²t subjected by the target circuit would not increase with the increase in the current across the shunt.

In this embodiment, a voltage across a shunt of a target circuit is integrated by a determination circuit 110 to obtain a corresponding integral voltage. Once the integral voltage reaches a first threshold, the target circuit is cut off, and the time for the integral voltage to reach the first threshold is configured to be inversely proportional to the value of the voltage across the shunt. This means the greater the current in the target circuit is, the shorter the time for cutting off the target circuit is. Therefore, the technical problem in related technologies where a Joule integral I²t sustained by the target circuit during a cut-off process exponentially increases with an increase in a current I due to the constant cut-off time, and the protection device is of poor protection under large current conditions, is alleviated.

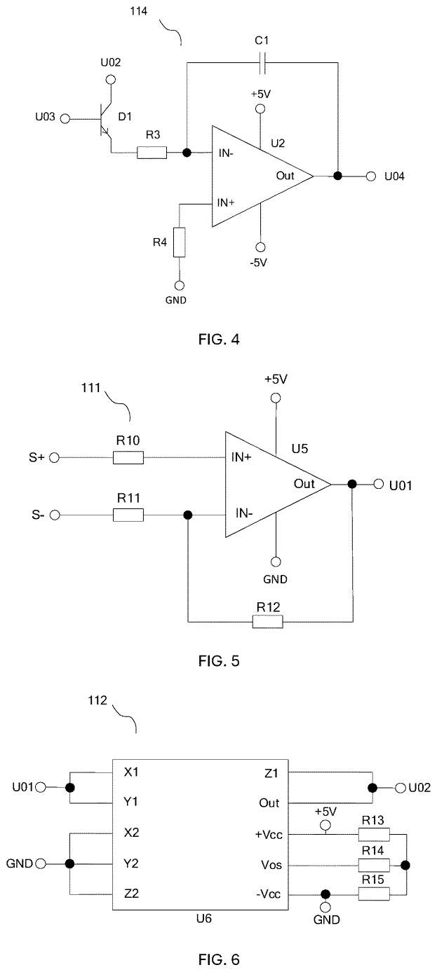

Referring to FIG. 3 and FIG. 4, in some embodiments, the determination circuit 110 includes an integrating circuit 114. The integrating circuit 114 is electrically connected to the shunt to receive the voltage across the shunt. The integrating circuit 114 integrates the voltage across the shunt to obtain an integral voltage.

For example, the integrating circuit 114 includes a first operational amplifier U2, a first resistor R3, a second resistor R4, and a first capacitor C1. An inverting input terminal of the first operational amplifier U2 receives the voltage across the shunt through the first resistor R3. A non-inverting input terminal of the first operational amplifier U2 is electrically connected to a first power line through the second resistor R4. An output terminal of the first operational amplifier U2 is configured to output the integral voltage. A first terminal of the first capacitor C1 is electrically connected to the inverting input terminal of the first operational amplifier U2, and a second terminal of the first capacitor C1 is electrically connected to the output terminal of the first operational amplifier U2.

The first operational amplifier U2, the first resistor R3, and the second resistor R4 constitute the integrating circuit 114. A voltage at the output terminal of the first operational amplifier U2 per unit time is determined by a voltage input into the inverting input terminal of the first operational amplifier U2. The higher the voltage at the inverting input terminal of the first operational amplifier U2 is, the higher the voltage at the output terminal of the first operational amplifier U2 per unit time is.

Referring to FIG. 3, FIG. 5, and FIG. 6, in an embodiment, the determination circuit 110 further includes an absolute value multiplying circuit 112 and a differential amplifying circuit 111. The absolute value multiplying circuit 112 is electrically connected between the differential amplifying circuit 111 and the first resistor R3. The absolute value multiplying circuit 112 is configured to multiply the voltage on the differential amplifying circuit 111 to obtain a first operational voltage. The integral voltage is obtained based on the first operational voltage through the first operational amplifier U2.

The differential amplifying circuit 111 is electrically connected between the shunt and the absolute value multiplying circuit 112. The differential amplifying circuit 111 is configured to amplify the voltage across the shunt to obtain a second operational voltage and output the second operational voltage to the absolute value multiplying circuit 112.

In some embodiments, the differential amplifying circuit 111 includes a fourth operational amplifier U5, an eighth resistor R10, a ninth resistor R11, and a tenth resistor R12. A non-inverting input terminal of the fourth operational amplifier U5 is electrically connected to a first terminal of the shunt through the eighth resistor R10, and an inverting input terminal of the fourth operational amplifier U5 is electrically connected to a second terminal of the shunt through the ninth resistor R11. The inverting input terminal of the fourth operational amplifier U5 is electrically connected to an output terminal of the fourth operational amplifier U5 through the tenth resistor R12.

The fourth operational amplifier U5 is configured to perform differential amplification on the voltage across the shunt. That helps prevent the resulting output from the absolute value multiplying circuit 112 from being insufficient for processing by the integrating circuit 114, when the voltage across the shunt is too low.

The absolute value multiplying circuit 112 includes a multiplying module U6, which has an input terminal electrically connected to the output terminal of the fourth operational amplifier U5. An output terminal of the multiplying module U6 is electrically connected to the inverting input terminal of the first operational amplifier U2, and the multiplying module U6 multiplies the second operational voltage to obtain the first operational voltage.

In some embodiments, the multiplying module U6 is implemented through a multiplying chip, such as a multiplying chip of model MPY100 of Texas Instruments. An input terminal X1 of the multiplying chip is electrically connected to the output terminal of the fourth operational amplifier U5, and an output terminal OUT of the multiplying chip is electrically connected to the inverting input terminal of the first operational amplifier U2. A first voltage pin +vcc, a second voltage pin vos, and a third voltage pin-vcc of the multiplying chip are grounded through the resistor R13, the resistor R14, and the resistor R15, respectively.

Other circuits with multiplication functions may also be used to implement functions described above.

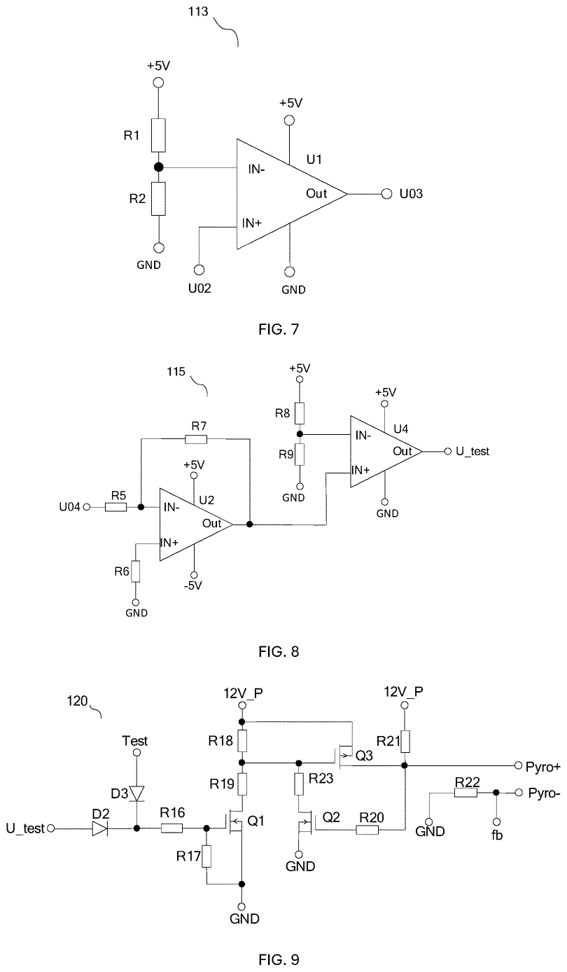

Referring to FIG. 3, FIG. 4, and FIG. 7, in some embodiments, the integrating circuit 114 further includes a first transistor D1. An input terminal of the first transistor D1 is electrically connected to an output terminal of the absolute value multiplying circuit 112, and an output terminal of the first transistor D1 is electrically connected to the first resistor R3. The determination circuit 110 further includes a threshold judgment circuit 113, which has an input electrically connected to the output terminal of the absolute value multiplying circuit 112. An output terminal of the threshold judgment circuit 113 is electrically connected to a control terminal of the first transistor D1. Once the first operational voltage is higher than a second threshold, the threshold judgment circuit 113 will turn on the first transistor D1.

In some embodiments, the threshold judgment circuit 113 includes a fifth operational amplifier U1, an eleventh resistor R1, and a twelfth resistor R2. A first terminal of the eleventh resistor R1 is electrically connected to a second power line, a second terminal of the eleventh resistor R1 is electrically connected to a first terminal of the twelfth resistor R2, and a second terminal of the twelfth resistor R2 is electrically connected to the first power line. An inverting input terminal of the fifth operational amplifier U1 is electrically connected to a common terminal between the eleventh resistor R1 and the twelfth resistor R2, and a non-inverting input terminal of the fifth operational amplifier U1 is electrically connected to the output terminal OUT of the multiplying chip.

The fifth operational amplifier U1, the eleventh resistor R1, and the twelfth resistor R2 constitute a comparator circuit. And the first operational voltage output by the multiplying chip is compared with a voltage across the twelfth resistor R2, that is, the voltage across the twelfth resistor R2 is the second threshold. The second threshold is adjusted by adjusting resistance values of the eleventh resistor R1 and the twelfth resistor R2.

Once the first operational voltage output by the multiplying chip is higher than the voltage across the twelfth resistor R2, the fifth operational amplifier U1 outputs a first control voltage to turn on the first transistor D1. The first operational voltage output by the multiplying chip is input to the inverting input terminal of the first operational amplifier U2, and the first operational amplifier U2 operates on the first operational voltage to obtain the integral voltage.

Referring to FIG. 8, in an embodiment, the determination circuit 110 further includes a determination triggering circuit 115. The determination triggering circuit 115 is electrically connected to an output terminal of the integrating circuit 114. Once the integral voltage reaches a first threshold, the determination triggering circuit 115 generates a triggering signal.

In some embodiments, the determination triggering circuit 115 includes a second operational amplifier U3, a third operational amplifier U4, a third resistor R5, a fourth resistor R6, a fifth resistor R7, a sixth resistor R8, and a seventh resistor R9.

A first terminal of the sixth resistor R8 is electrically connected to the second power line, a second terminal of the sixth resistor R8 is electrically connected to a first terminal of the seventh resistor R9, and a second terminal of the seventh resistor R9 is electrically connected to the first power line.

An inverting input terminal of the second operational amplifier U3 is electrically connected to the output terminal of the integrating circuit 114 through the third resistor R5. A non-inverting input terminal of the second operational amplifier U3 is electrically connected to the first power line through the fourth resistor R6. The inverting input terminal of the second operational amplifier U3 is electrically connected to an output terminal of the second operational amplifier U3 through the fifth resistor R7.

A non-inverting input terminal of the third operational amplifier U4 is electrically connected to the output terminal of the second operational amplifier U3, an inverting input terminal of the third operational amplifier U4 is electrically connected to a common terminal between the sixth resistor R8 and the seventh resistor R9, and an output terminal of the third operational amplifier U4 is configured to output a triggering signal.

The second operational amplifier U3, the third resistor R5, the fourth resistor R6, and the fifth resistor constitute a reverse proportional amplifying circuit. The second operational amplifier U3 reversely amplifies the integral voltage to obtain a third operational voltage and outputs the third operational voltage to the non-inverting input terminal of the third operational amplifier U4.

The third operational amplifier U4, the sixth resistor R8, and the seventh resistor R9 constitute a comparator. The third operational voltage is compared with a voltage across the seventh resistor R9, that is, the voltage across the seventh resistor R9 is the first threshold. The first threshold is adjusted by adjusting resistance values of the sixth resistor R8 and the seventh resistor R9. Once the third operational voltage is higher than the first threshold, the third operational amplifier U4 outputs a triggering signal.

Based on the scheme of the circuit cut-off triggering device 100 in this embodiment, the Joule integral expected to be sustained by the target circuit during a cut-off process is set as the first threshold. Thus, the Joule integral sustained by the target circuit during the cut-off process is a constant value. A time for cutting off the target circuit under large current conditions is less than a time for cutting off the target circuit under small current conditions. The Joule integral sustained by the target circuit during the cut-off process under large current conditions is the same as the Joule integral sustained by the target circuit during the cut-off process under small current conditions, so that the Joule integral I²t sustained by the target circuit would not increase with the increase in the current across the shunt.

Referring to FIG. 3 to FIG. 9, the differential amplifying circuit 111 amplifies the voltage U₀ across the shunt and outputs a second operational voltage U₀₁=β*U₀=B*I₀*R₀ (β: differential amplification factor), in which β is the differential amplification factor of the fourth operational amplifier U5, I₀ is the current flowing through the shunt, and R₀ is the voltage across the shunt.

The absolute value multiplying circuit 112 multiplies the second operational voltage U₀₁ to obtain a first operational voltage U₀₂−U₀₁²=I₀²*(β*R₀)².

The threshold judgment circuit 113 compares the first operational voltage U₀₂ with a second threshold Uₐ. It can be understood that comparing the first operational voltage U₀₂ with the second threshold Uₐ is actually comparing the current I₀ passing through the shunt with a current threshold Iₐ (Iₐ is the corresponding current across the shunt in case that the voltage across the shunt reaches the second threshold).

Once the first operational voltage U₀₂ is higher than the second threshold Uₐ, the threshold judgment circuit 113 outputs a control voltage U₀₃ to turn on the first transistor D1, and the first operational voltage U₀₂ is input to the integrating circuit 114. The integrating circuit 114 integrates U₀₂ and outputs an integral voltage

$${U}_{04} = - \frac{1}{{R}_{3} * {C}_{1}} {\int }_{0}^{t} {U}_{02} ( t ) dt = - \frac{{( β * {R}_{0} )}^{2}}{{R}_{3} * {C}_{1}} * {I}_{0}^{2} t$$

to the determination triggering circuit 115.

The second operational amplifier U3 in the determination triggering circuit 115 reversely amplifies the integral voltage U₀₄ to obtain a third operational voltage

$${U}_{b} = - \frac{R 7}{R 5} {U}_{04} = \frac{{R}_{7} * {( β * {R}_{0} )}^{2}}{{R}_{5} * {R}_{3} * C 1} * {I}_{0}^{2} t ,$$

and sends the third operational voltage U_{b} to the third operational amplifier U4. The third operational amplifier U4 compares the third operational voltage Up with the first threshold

$${U}_{c} = \frac{R 7 * {( β * R 0 )}^{2}}{R 5 * R 3 * C 1} * {I}^{2} t ,$$

in which I²t is the Joule integral expected to be sustained by the target circuit during a cut-off process. Once the third operational voltage U_{b} is higher than the first threshold Uc, the third operational amplifier U4 outputs a triggering signal U_ₜₑₛₜ to trigger the protection device Pyrofuse to cut off the target circuit.

A coefficient part

$$\frac{R 7 * {( β * R 0 )}^{2}}{R 5 * R 3 * C 1}$$

of the third operational voltage U_{b} is configured to be equal to the coefficient part of the first threshold Uc, and a comparison between the third operational voltage U_{b} and the first threshold Uc is considered as a comparison between I₀²t and I²t. Therefore, the Joule integral I²t expected to be sustained by the target circuit during a cut-off process is configured as the first threshold, so that in case that the first threshold is constant, the circuit cut-off triggering device 100 ensures that the Joule integral sustained by the target circuit during a cut-off process under large current conditions is the same as the Joule integral sustained by the target circuit during a cut-off process under small current conditions.

Referring to FIG. 2 and FIG. 9, in an embodiment, the circuit cut-off triggering device 100 further includes a triggering circuit 120. The triggering circuit 120 is electrically connected to the determination circuit 110. The triggering circuit 120 is configured to drive a protection device Pyrofuse in the target circuit based on a triggering signal. Once the protection device Pyrofuse is driven, the target circuit is cut off.

In some embodiments, the triggering circuit 120 includes a second transistor Q1, a third transistor Q3, a thirteenth resistor R16, a fourteenth resistor R17, a fifteenth resistor R19, and a sixteenth resistor R18.

A control terminal of the second transistor Q1 is electrically connected to an output terminal of the determination circuit 110, and an input terminal of the second transistor Q1 is electrically connected to the first power line.

A control terminal of the third transistor Q3 is electrically connected to an output terminal of the second transistor Q1, an input terminal of the third transistor Q3 is electrically connected to a third power line, an output terminal of the third transistor Q3 is electrically connected to a first control terminal of the protection device Pyrofuse, and a second control terminal of the protection device Pyrofuse is grounded through a second control terminal resistor R22.

Once the second transistor Q1 is turned on, a voltage on the first power line pulls down a voltage at the control terminal of the third transistor Q3 to turn on the third transistor Q3. The third transistor Q3 outputs a voltage on the third power line to a first control terminal of the protection device Pyrofuse to drive the protection device Pyrofuse to cut off the target circuit.

A thirteenth resistor R16 is electrically connected between the control terminal of the second transistor Q1 and the output terminal of the determination circuit 110. The control terminal of the second transistor Q1 is electrically connected to the first power line through the fourteenth resistor R17, preventing damage to the second transistor Q1 in case the voltage across the triggering signal becomes excessive.

A fifteenth resistor R19 is electrically connected between the control terminal of the third transistor Q3 and the output terminal of the second transistor Q1, and the control terminal of the third transistor Q3 is electrically connected to the third power line through a sixteenth resistor R18.

In some embodiments, the triggering circuit 120 further includes a maintaining unit, and the maintaining unit includes a fourth transistor Q2, a seventeenth resistor R21, an eighteenth resistor R20, and a nineteenth resistor R23.

A first terminal of the seventeenth resistor R21 is electrically connected to the output terminal of the third transistor Q3, a second terminal of the seventeenth resistor is electrically connected to the third power line, a control terminal of the fourth transistor Q2 is electrically connected to the output terminal of the third transistor Q3 through the eighteenth resistor R20, an input terminal of the fourth transistor Q2 is electrically connected to the first power line, and an output terminal of the fourth transistor Q2 is electrically connected to the control terminal of the third transistor Q3 through the nineteenth resistor R23.

Once the second transistor Q1 is turned on to pull down a voltage at the control terminal of the third transistor Q3, the third transistor Q3 is turned on, a voltage on the third power line is transmitted to the control terminal of the fourth transistor Q2, so that the fourth transistor Q2 is turned on to further pull down the voltage at the control terminal of the third transistor Q3. Thus, the third transistor Q3 is kept being turned on to continuously drive the protection device Pyrofuse to cut off the target circuit, thus the safety of the target circuit is improved. Resistance values of the seventeenth resistor R21 and the eighteenth resistor R20 are adjusted to prevent the fourth transistor Q2 from being turned on in case that the third transistor Q3 is not yet turned on.

For example, the first power line provides a low potential voltage, such as ground, the second power line provides a +5V voltage, and the third power line provides a 12V voltage.

In some embodiments, the circuit cut-off triggering device 100 further includes a power module 130, and the power module is configured to provide corresponding voltages to the first power line and the second power line. For example, the power module 130 is implemented with a power management chip, which converts an external voltage such as a voltage output by the power module in a BMS (Battery Management System) of a battery pack into corresponding voltages on the first power line and the second power line. For example, the corresponding voltage on the third power line is directly provided by the power module in the BMS.

In some embodiments, the circuit cut-off triggering device 100 should be electrically connected in a circuit between the battery pack 200 and the load 300, and the target circuit is a main circuit of the battery pack. The main circuit of the battery pack 200 includes a protection device Pyrofuse, a shunt, a positive relay S1, a negative relay S2, a pre-charge relay S3, and a pre-charge resistor Ry. The protection device Pyrofuse and the positive relay S1 are electrically connected in series between a positive electrode of the battery pack and a first input terminal of the load, and the shunt and the negative relay S2 are electrically connected in series between a negative electrode of the battery pack and a second input terminal of the load. The pre-charge relay S3 and the pre-charge resistor Ry are electrically connected in series, and electrically connected in parallel with the positive relay S1.

In an embodiment, the control terminal of the second transistor Q1 is further electrically connected to the BMS, and the BMS sends an active triggering signal Test to turn on the second transistor Q1.

In order to prevent the triggering signal sent by the determination triggering circuit 115 and the active triggering signal sent by the BMS from influencing each other, a diode is electrically connected between the output terminal of the determination triggering circuit 115 and the control terminal of the second transistor Q1, as well as between the BMS and the control terminal of the second transistor Q1.

In some embodiments, a first diode D2 is electrically connected between the output terminal of the third operational amplifier U4 and the control terminal of the second transistor Q1. An anode electrode of the first diode D2 is electrically connected to the output terminal of the third operational amplifier U4, and a cathode electrode of the first diode D2 is electrically connected to the control terminal of the second transistor Q1. A control signal output terminal of the BMS is electrically connected to the anode electrode of the second diode D3, and the cathode electrode of the second diode D3 is electrically connected to the control terminal of the second transistor Q1.

In this embodiment of the present disclosure, the control signals of the circuit cut-off triggering device 100 and the BMS are both configured to drive the protection device Pyrofuse and control the target circuit to be cut off without interfering with each other.

In an embodiment, the BMS is electrically connected to the second control terminal of the protection device Pyrofuse through a feedback terminal to detect a triggering state of the protection device Pyrofuse. For example, the feedback terminal of the BMS is electrically connected to the second control terminal of the protection device Pyrofuse and a terminal of the second control terminal resistor R22 closer to the second control terminal. The seventeenth resistor R21, the first control terminal of the protection device Pyrofuse, and the second control terminal resistor R22 constitute a state detection circuit. Once the protection device Pyrofuse is working, the first control terminal and the second control terminal of the protection device Pyrofuse are in an off state, and the feedback terminal of the BMS receives a low level, so that the BMS monitors a working state of the protection device Pyrofuse based on a voltage at the feedback terminal.

In the embodiments of the present disclosure, a voltage across a shunt of a target circuit is integrated by a determination circuit to obtain a corresponding integral voltage, and the integral voltage is compared with a first threshold. In case that the integral voltage reaches the first threshold voltage, a triggering signal is generated to cut off the target circuit. Since a growth rate of the integral voltage is configured to be inversely proportional to a magnitude of the voltage across the shunt, the higher the voltage across the shunt is, the shorter the time it takes for the integral voltage to reach the first threshold voltage. That is, the time for the integral voltage to reach the first threshold is configured to be inversely proportional to the magnitude of the voltage across the shunt. As such, the greater the current in the target circuit is, the shorter the time for cutting off the target circuit is. Therefore, compared to the related technologies where the target circuit cannot be cut off by a trigger in time under high current conditions due to the constant cut-off time, resulting in an exponential increase in a Joule integral I²t sustained by the target circuit during a cut-off process with an increase in the current I, the disclosed embodiments improves the protection of the trigger.

What is claimed is:

1. A circuit cut-off triggering device for a target circuit, the circuit cut-off triggering device comprising:
a determination circuit configured to integrate a voltage across a shunt to obtain an integral voltage, and generate a triggering signal in response to the integral voltage reaching a first threshold, the triggering signal causes the target circuit to be cut off,
wherein a time for the integral voltage to reach the first threshold is inversely proportional to a magnitude of the voltage across the shunt.

2. The circuit cut-off triggering device of claim 1, wherein the determination circuit comprises:
an integrating circuit electrically connected to the shunt and configured to integrate the voltage across the shunt to obtain the integral voltage.

3. The circuit cut-off triggering device of claim 2, wherein the integrating circuit comprises: a first operational amplifier, a first resistor, a second resistor, and a first capacitor,
wherein an inverting input terminal of the first operational amplifier is configured to receive the voltage across the shunt through the first resistor, a non-inverting input terminal of the first operational amplifier is electrically connected to a first power line through the second resistor, an output terminal of the first operational amplifier is configured to output the integral voltage, a first terminal of the first capacitor is electrically connected to the inverting input terminal of the first operational amplifier, and a second terminal of the first capacitor is electrically connected to the output terminal of the first operational amplifier.

4. The circuit cut-off triggering device of claim 3, wherein the determination circuit further comprises an absolute value multiplying circuit electrically connected between the shunt and the first resistor, the absolute value multiplying circuit being configured to multiply the voltage across the shunt to obtain a first operational voltage, wherein the first operational amplifier is configured to generate the integral voltage based on the first operational voltage.

5. The circuit cut-off triggering device of claim 4, wherein the determination circuit further comprises a differential amplifying circuit electrically connected between the shunt and the absolute value multiplying circuit, the differential amplifying circuit being configured to amplify the voltage across the shunt and output an amplified voltage to the absolute value multiplying circuit.

6. The circuit cut-off triggering device of claim 5, wherein the differential amplifying circuit comprises: a fourth operational amplifier, an eighth resistor, a ninth resistor, and a tenth resistor,
wherein a non-inverting input terminal of the fourth operational amplifier is electrically connected to a first terminal of the shunt through the eighth resistor, an inverting input terminal of the fourth operational amplifier is electrically connected to a second terminal of the shunt through the ninth resistor, and an output terminal of the fourth operational amplifier is electrically connected to the absolute value multiplying circuit, wherein the inverting input terminal of the fourth operational amplifier is electrically connected to the output terminal of the fourth operational amplifier through the tenth resistor.

7. The circuit cut-off triggering device of claim 6, wherein the absolute value multiplying circuit comprises a multiplying module, wherein an input terminal of the multiplying module is electrically connected to the output terminal of the fourth operational amplifier, and an output terminal of the multiplying module is electrically connected to the inverting input terminal of the first operational amplifier,
wherein the differential amplifying circuit is configured to amplify the voltage across the shunt to obtain a second operational voltage, the multiplying module being configured to multiply the second operational voltage to obtain the first operational voltage.

8. The circuit cut-off triggering device of claim 4, wherein the integrating circuit further comprises a first transistor,
wherein an input terminal of the first transistor is electrically connected to an output terminal of the absolute value multiplying circuit and an output terminal of the first transistor is electrically connected to the first resistor,
wherein the determination circuit further comprises a threshold judgment circuit, wherein an input terminal of the threshold judgment circuit is electrically connected to the output terminal of the absolute value multiplying circuit and an output terminal of the threshold judgment circuit is electrically connected to a control terminal of the first transistor, the threshold judgment circuit being configured to turn on the first transistor in response to the first operational voltage being higher than a second threshold.

9. The circuit cut-off triggering device of claim 8, wherein the threshold judgment circuit comprises a fifth operational amplifier, an eleventh resistor, and a twelfth resistor; a first terminal of the eleventh resistor is electrically connected to a second power line, a second terminal of the eleventh resistor is electrically connected to a first terminal of the twelfth resistor, a second terminal of the twelfth resistor is electrically connected to the first power line, an inverting input terminal of the fifth operational amplifier is electrically connected to a common terminal between the eleventh resistor and the twelfth resistor, a non-inverting input terminal of the fifth operational amplifier is electrically connected to an output terminal of the absolute value multiplying circuit, and an output terminal of the fifth operational amplifier is electrically connected to the control terminal of the first transistor.

10. The circuit cut-off triggering device of claim 2, wherein the determination circuit further comprises a determination triggering circuit electrically connected to an output terminal of the integrating circuit configured to generate the triggering signal in response to the integral voltage reaches the first threshold.

11. The circuit cut-off triggering device of claim 10, wherein the determination triggering circuit comprises a second operational amplifier, a third operational amplifier, a third resistor, a fourth resistor, a fifth resistor, a sixth resistor, and a seventh resistor,
wherein an inverting input terminal of the second operational amplifier is electrically connected to the output terminal of the integrating circuit through the third resistor, a non-inverting input terminal of the second operational amplifier is electrically connected to the first power line through the fourth resistor, and the inverting input terminal of the second operational amplifier is electrically connected to an output terminal of the second operational amplifier through the fifth resistor,
wherein a first terminal of the sixth resistor is electrically connected to a second power line, a second terminal of the sixth resistor is electrically connected to a first terminal of the seventh resistor, and a second terminal of the seventh resistor is electrically connected to the first power line,
wherein a non-inverting input terminal of the third operational amplifier is electrically connected to the output terminal of the second operational amplifier, an inverting input terminal of the third operational amplifier is electrically connected to a common terminal between the sixth resistor and the seventh resistor, and an output terminal of the third operational amplifier is configured to output the triggering signal.

12. The circuit cut-off triggering device of claim 1, further comprising a triggering circuit electrically connected to the determination circuit and configured to drive a protection device in the target circuit in response to the triggering signal to cut off the target circuit.

13. The circuit cut-off triggering device of claim 12, wherein the triggering circuit comprises:
a second transistor, wherein a control terminal of the second transistor is electrically connected to an output terminal of the determination circuit and an input terminal of the second transistor is electrically connected to a first power line; and
a third transistor, wherein a control terminal of the third transistor is electrically connected to an output terminal of the second transistor, an input terminal of the third transistor is electrically connected to a third power line, and an output terminal of the third transistor is electrically connected to a control terminal of the protection device.

14. The circuit cut-off triggering device of claim 13, further comprising a power module configured to provide voltages to the first power line and a second power line, respectively.

15. The circuit cut-off triggering device of claim 13, wherein the control terminal of the second transistor is electrically connected to a battery management system (BMS), the BMS being configured to send an active triggering signal to turn on the second transistor.

16. The circuit cut-off triggering device of claim 15, wherein a feedback terminal of the BMS is electrically connected to a second control terminal of the protection device and is configured to monitor a working state of the protection device based on a voltage at the feedback terminal.

17. The circuit cut-off triggering device of claim 12, wherein the triggering circuit further comprises a fourth transistor, a seventeenth resistor, an eighteenth resistor, and a nineteenth resistor.

18. The circuit cut-off triggering device of claim 15, wherein the circuit cut-off triggering device is configured such that when the second transistor is turned on, a voltage on the first power line pulls down a voltage at the control terminal of the third transistor to turn on the third transistor.

19. The circuit cut-off triggering device of claim 15, wherein a thirteenth resistor is electrically connected between the control terminal of the second transistor and the output terminal of the determination circuit, and the control terminal of the second transistor is further electrically connected to the first power line.

20. The circuit cut-off triggering device of claim 15, wherein a fifteenth resistor is electrically connected between the control terminal of the third transistor and the output terminal of the second transistor, and the control terminal of the third transistor is further electrically connected to the third power line.
